(19) United States
(12) Patent Application Publication
(10) Pub. No.: US 2026/0362624 A1
(43) Pub. Date: Nov. 12, 2026

(54) SEMICONDUCTOR DEVICE AND VEHICLE

(71) Applicant: FUJI ELECTRIC CO., LTD., Kawasaki-shi (JP)

(72) Inventor: Akira IKEGAMI, Kawasaki-shi (JP)

(73) Assignee: FUJI ELECTRIC CO., LTD., Kawasaki-shi (JP)

(21) Appl. No.: 19/723,651

(22) Filed: Jun. 29, 2026

Related U.S. Application Data
(63) Continuation of application No. PCT/JP2025/020882, filed on Jun. 10, 2025.

(30) Foreign Application Priority Data
Jul. 12, 2024 (JP) 2024-112491

(51) Int. Cl. H05K 7/14; H02M 7/00

(52) U.S. Cl. CPC H05K 7/14324; H02M 7/003

(57) ABSTRACT

A semiconductor device, including: a semiconductor module, having an insulating member, and first and second main terminals each having an outer terminal portion exposed to an outside, the two outer terminal portions being disposed adjacent to each other on a first surface of the insulating member; and a capacitor module, including a first external terminal that is connected to the outer terminal portion of the first main terminal with a first connection surface therebetween, and a second external terminal that is located between the first external terminal and the second main terminal of the semiconductor module, and is connected to a region of the outer terminal portion of the second main terminal. The first external terminal of the capacitor module has an opening region directly above the region of the outer terminal portion of the second main terminal with respect to a direction perpendicular to the first connection surface.

### CROSS-REFERENCE TO RELATED APPLICATIONS

This is a continuation application of International Application PCT/JP 2025/020882 filed on Jun. 10, 2025 which claims priority from a Japanese Patent Application No. 2024-112491 filed on Jul. 12, 2024, the contents of which are incorporated herein by reference.

### TECHNICAL FIELD

The present invention relates to a semiconductor device and a vehicle.

### BACKGROUND ART

A semiconductor device used in a power converter includes a semiconductor module in which an inverter circuit is formed and a capacitor module connected to the semiconductor module (Patent Literatures 1 to 4). In a semiconductor module used for this type of semiconductor device, there is a semiconductor module in which a first main terminal and a second main terminal respectively connected to a first external terminal and a second external terminal of a capacitor module are arranged in an extending direction of the first external terminal and the second external terminal from a housing of the capacitor module.

### CITATION LIST

### Patent Literature

Patent Literature 1: JP 2018-190965 A

Patent Literature 2: JP 2010-219216 A

Patent Literature 3: JP 2023-62046 A

Patent Literature 4: JP 2009-5512 A

### SUMMARY OF INVENTION

### Technical Problem

In the above-described semiconductor device, it takes time and effort to connect the main terminals of the semiconductor module to the external terminals of the capacitor module. The present invention has been made in view of the above-mentioned circumstances, and an object thereof is to facilitate the connection work between the main terminals of the semiconductor module and the external terminals of the capacitor module.

### Solution to Problem

A semiconductor device according to one aspect of the present invention includes a semiconductor module in which an outer terminal portion exposed to the outside of a first main terminal and an outer terminal portion exposed to the outside of a second main terminal are disposed adjacent to each other on a first surface of an insulating member, and a capacitor module including a first external terminal and a second external terminal, the first external terminal being connected to the outer terminal portion of the first main terminal, the second external terminal being located between the first external terminal and the second main terminal and being connected to the outer terminal portion of the second main terminal. The first external terminal of the capacitor module has a shape having an opening region overlapping the outer terminal portion of the second main terminal in plan view of a connection surface with the outer terminal portion of the first main terminal, and the second external terminal of the capacitor module is connected to a region of the outer terminal portion of the second main terminal, the region being located within the opening region of the first external terminal in the plan view.

### Advantageous Effects of Invention

According to the present invention, the connection work between the main terminals of the semiconductor module and the external terminals of the capacitor module can be facilitated.

### BRIEF DESCRIPTION OF DRAWINGS

FIG. 1 is a top view illustrating a configuration example of a semiconductor device according to an embodiment.

FIG. 2 is a cross-sectional view illustrating a cross-sectional configuration of the semiconductor device in FIG. 1.

FIG. 3 is a perspective view illustrating a configuration example of a first main terminal and a second main terminal of a semiconductor module.

FIG. 4 is a circuit diagram illustrating a circuit configuration example of the semiconductor device.

FIG. 5 is a partially enlarged top view illustrating a first example of the shapes of the first main terminal and the second main terminal of the semiconductor module and a first external terminal and a second external terminal of a capacitor module.

FIGS. 6A and 6B are partially enlarged top views illustrating another example of the shapes of the first main terminal and the second main terminal of the semiconductor module and the first external terminal and the second external terminal of the capacitor module.

FIG. 7 is a partially enlarged top view (FIG. 7A) and a cross-sectional view (FIG. 7B) illustrating a modification of the first external terminal of the capacitor module.

FIG. 8 is a bottom view (FIG. 8A) and a cross-sectional view (FIG. 8B) illustrating a modification of the second external terminal of the capacitor module.

FIG. 9 is a top view illustrating another configuration example of the semiconductor device.

FIG. 10 is a circuit diagram illustrating a circuit configuration example of the semiconductor device in FIG. 9.

FIG. 11 is a schematic plan view illustrating an example of a vehicle to which the semiconductor device according to the embodiment is applied.

### DESCRIPTION OF EMBODIMENTS

Hereinafter, embodiments of the present invention will be described in detail with reference to the drawings. Note that the X-axis, the Y-axis, and the Z-axis in each of the drawings to be referred to are illustrated for the purpose of defining a plane and a direction in the exemplified semiconductor device or the like. The X-axis, the Y-axis, and the Z-axis are orthogonal to each other and form a right-handed system. In the following description, a direction parallel to the X-axis is referred to as an X direction, a direction parallel to the Y-axis is referred to as a Y direction, and a direction parallel to the Z-axis is referred to as a Z direction. Further, in a case in which each of the X direction, the Y direction, and the Z direction is associated with a direction of an arrow (positive or negative) of a corresponding one of the X-axis, the Y-axis, and the Z-axis illustrated, a “positive side” or a “negative side” is added.

In the present specification, the Z direction may be referred to as an upward-and-downward direction. In the present specification, the expressions “on” and “upper” are intended to mean the positive side in the Z direction with respect to a reference surface, a member, a position, and the like, and the expressions “below” and “lower” are intended to mean the negative side in the Z direction with respect to the reference surface, the member, the position, and the like. For example, when it is described that “a member B is disposed on a member A”, the member B is disposed on the positive side in the Z direction as viewed from the member A. Further, when an “upper surface of the member A” is described, the surface is positioned at the end of the member A on the positive side in the Z direction and faces the positive side in the Z direction. In the present specification, “top view” is intended to mean a plan view when a target article (for example, a semiconductor device or the like) is viewed from the positive side in the Z direction. In the present specification, “side view” is intended to mean a plan view when a target article is viewed from the negative side in the X direction or the positive side in the X direction, and a plan view when viewed from the negative side in the X direction may be referred to as a “left side view”, and a plan view when viewed from the positive side in the X direction may be referred to as a “right side view”. These directions and surfaces are terms used for the convenience of description, and a correspondence relationship with each of the directions of the X-axis, the Y-axis, and the Z-axis may change depending on an attachment posture of the semiconductor device and the like. For example, in the present specification, a surface of a semiconductor element facing a wiring board is referred to as a lower surface, and a surface opposite to the lower surface is referred to as an upper surface, but these terms are not limited thereto, and the surface facing the wiring board may be referred to as an upper surface, and the surface opposite thereto may be referred to as a lower surface. The lower surface and the upper surface of the semiconductor element may be referred to as side surfaces. In addition, an aspect ratio and a size relationship between respective members in each drawing are merely schematically represented, and do not necessarily coincide with a relationship in a semiconductor device or the like actually manufactured. For convenience of description, it is also assumed that the size relationship between the respective members is exaggerated. In addition, for convenience of description, some of the cross-sectional views illustrate cross-sectional configurations of the semiconductor device cut along a virtual cutting line that cannot be accurately illustrated in the top view (plan view). Furthermore, some of the cross-sectional views schematically illustrate portions of the semiconductor device positioned at the back of the cross section.

Furthermore, the semiconductor device exemplified in the following description may be applied to, for example, a power conversion device for industrial or electrical equipment (for example, automotive electronic equipment). Specifically, the semiconductor device exemplified in the present specification includes a semiconductor module in which an inverter circuit is formed, and a capacitor module electrically connected to the inverter circuit of the semiconductor module. Therefore, in the following description, detailed descriptions of configurations, functions, operations, manufacturing methods, and the like of the exemplified semiconductor device that are identical to or similar to those of known semiconductor devices will be omitted.

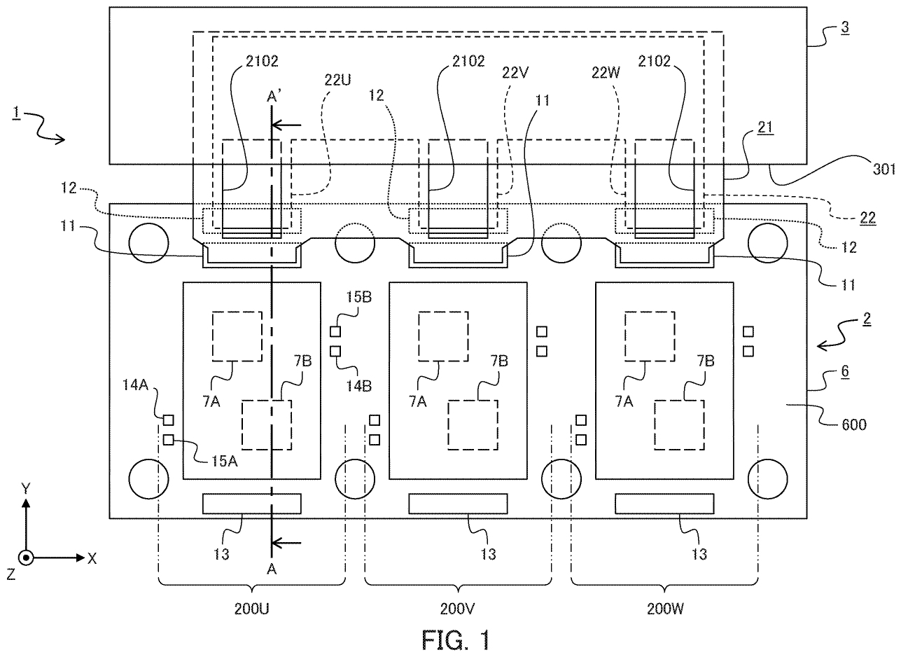

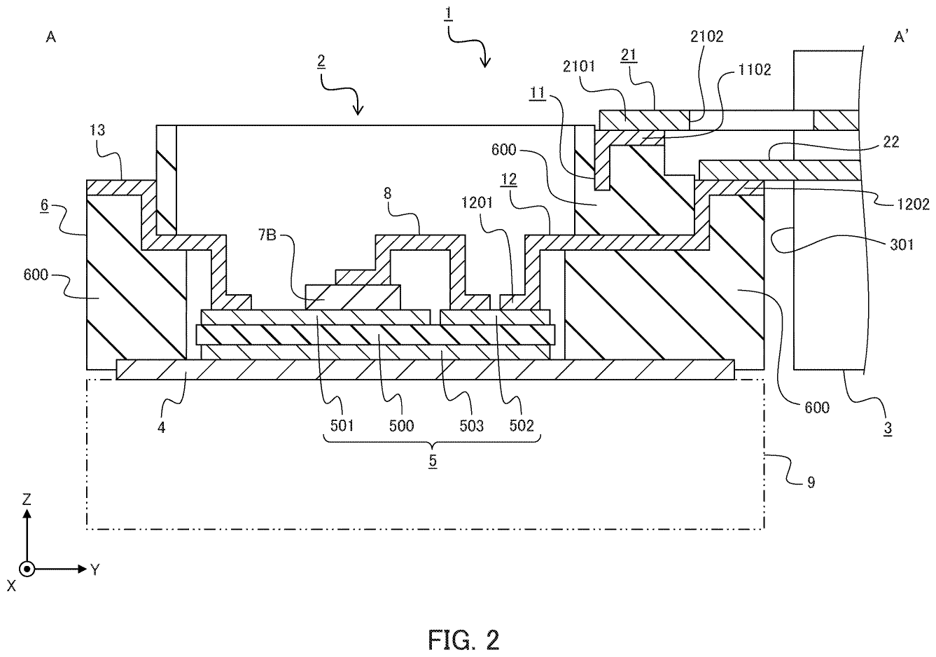

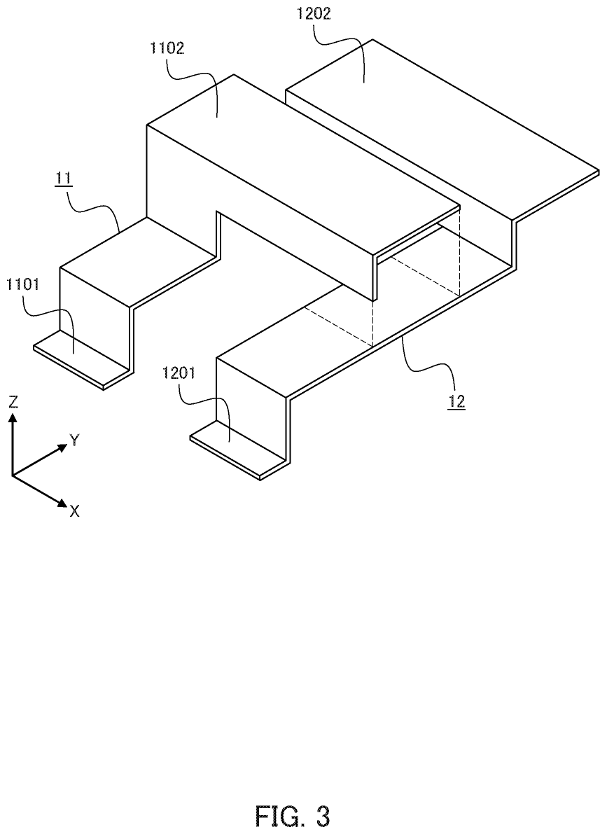

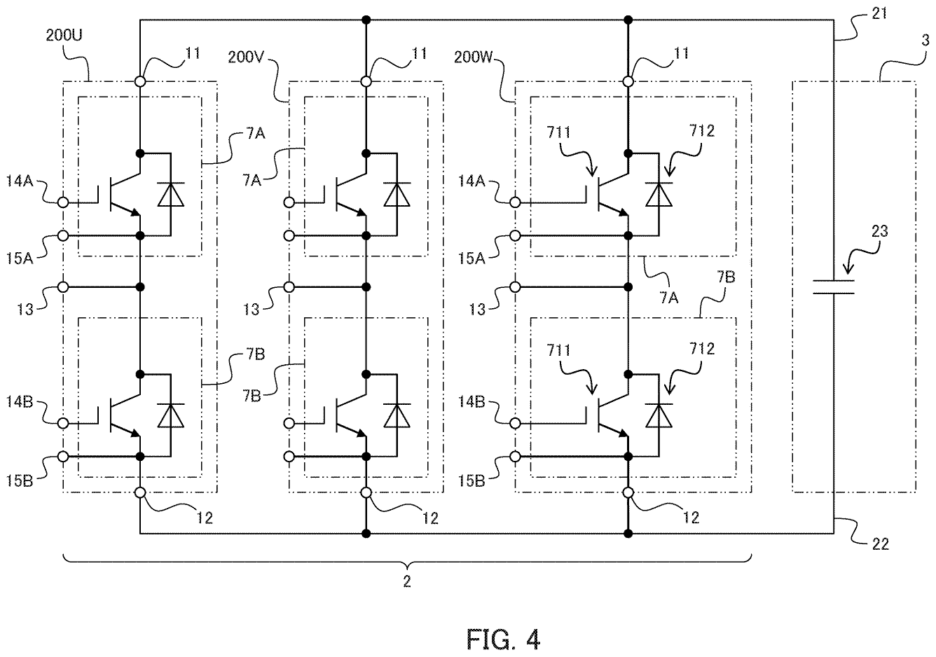

FIG. 1 is a top view illustrating a configuration example of a semiconductor device according to an embodiment. FIG. 2 is a cross-sectional view illustrating a cross-sectional configuration of the semiconductor device in FIG. 1. FIG. 3 is a perspective view illustrating a configuration example of a first main terminal and a second main terminal of a semiconductor module. FIG. 4 is a circuit diagram illustrating a circuit configuration example of the semiconductor device. The cross-sectional view of FIG. 2 may be a cross-sectional configuration at a position of an alternate long and short dash line A-A′ in a semiconductor device 1 illustrated in FIG. 1.

The semiconductor device 1 illustrated in FIGS. 1 and 2 includes a semiconductor module 2 and a capacitor module 3. The semiconductor module 2 includes three inverter circuits 200U, 200V, and 200W having the same circuit configuration. For example, a half-bridge inverter circuit illustrated in FIG. 4 is formed in each of the inverter circuits 200U, 200V, and 200W. As an example, the inverter circuit 200 (for example, the inverter circuit 200U) formed in the semiconductor module 2 may include a wiring board 5 and a case 6 disposed on the upper surface of a heat dissipation plate 4, semiconductor elements 7A and 7B disposed on the upper surface of the wiring board 5, and a wiring member such as a lead 8. The case 6 is provided with main terminals 11 to 13, control terminals 14A and 14B, and auxiliary control terminals 15A and 15B, which are used as external terminals of the inverter circuit 200.

The heat dissipation plate 4 is a heat-conducting component that conducts heat generated by the semiconductor elements 7A and 7B during operation to a cooler 9, and may be, for example, a metal plate having high thermal conductivity, such as aluminum, an aluminum alloy, copper, or a copper alloy. The heat dissipation plate 4 may be a single (one-piece) plate-like member shared by the three inverter circuits 200U, 200V, and 200W, or may be a plate-like member provided separately for each inverter circuit. Heat-dissipating fins may be provided on the lower surface of the heat dissipation plate 4. The heat dissipation plate 4 may be one of the components of the cooler 9, or may be a plate-like member provided separately from the cooler 9 and attachable to the cooler 9. The cooler 9 applicable to the semiconductor device 1 according to the present embodiment is not limited to a specific cooling system or a specific structure. That is, in the semiconductor device 1 of the present embodiment, the cooler 9 is an arbitrary component, and the semiconductor device 1 may not include the cooler 9.

The wiring board 5 includes an insulating plate 500, conductor patterns 501 and 502 disposed on the upper surface of the insulating plate 500, and a metal plate 503 disposed on the lower surface of the insulating plate 500. On the upper surface of the insulating plate 500, a conductor pattern different from the conductor patterns 501 and 502 illustrated in FIG. 2 is also disposed. The wiring board 5 may be, for example, a direct copper bonding (DCB) substrate or an active metal brazing (AMB) substrate, but is not limited to such a board. The wiring board 5 may be referred to as a laminated substrate, an insulating circuit board, or the like.

The insulating plate 500 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃), and zirconium oxide (ZrO₂). The insulating plate 500 may be, for example, a substrate obtained by molding an insulating resin such as an epoxy resin, a substrate obtained by impregnating a base material such as glass fiber with an insulating resin, a substrate obtained by coating the surface of a flat plate-shaped metal core with an insulating resin, or the like. The conductor patterns 501 and 502 disposed on the upper surface of the insulating plate 500 and other conductor patterns (not illustrated) function as wiring in the inverter circuit 200 illustrated in FIG. 4. The conductor patterns disposed on the upper surface of the insulating plate 500, such as the conductor patterns 501 and 502, are formed of, for example, a metal foil such as copper or aluminum. The conductor patterns may be referred to as wiring patterns, conductive layers or conductive plates, conductor layers or conductor plates, or the like. The metal plate 503 provided on the lower surface of the insulating plate 500 functions as a heat-conducting component that conducts heat generated by the semiconductor elements 7A and 7B to the heat dissipation plate 4. The metal plate 503 is formed of, for example, a metal foil such as copper or aluminum. The metal plate 503 is bonded to the heat dissipation plate 4 by a bonding material such as solder. In the present specification, for convenience, the conductive layer disposed on the lower surface of the insulating plate 500 is referred to as the “metal plate 503” and is distinguished from the “conductor patterns” disposed on the upper surface of the insulating plate 500 and used as wiring. In the configuration of the semiconductor module 2, for example, an insulating resin layer corresponding to the insulating plate 500 may be formed on the upper surface of the heat dissipation plate 4 instead of the wiring board 5, and the conductor patterns 501 and 502 or the like may be disposed on the insulating resin layer.

The semiconductor elements 7A and 7B are circuit components sometimes referred to as semiconductor chips or dies, and each of the semiconductor elements 7A and 7B may be, for example, a reverse conducting (RC)-IGBT element in which an insulated gate bipolar transistor (IGBT) element 711, which is a switching element, and a diode element 712 connected in anti-parallel with the IGBT element 711 are formed (refer to FIG. 4). The diode element 712 may be referred to as a free wheeling diode (FWD). The switching elements of the semiconductor elements 7A and 7B are not limited to the IGBT elements 711, and may be, for example, power metal oxide semiconductor field effect transistor (MOSFET) elements, Bipolar Junction Transistor (BJT) elements, or the like. The diode elements 712 of the semiconductor elements 7A and 7B may be, for example, Schottky barrier diode (SBD) elements, junction barrier Schottky (JBS) diode elements, merged PN Schottky (MPS) diode elements, PN diode elements, or the like.

In the semiconductor elements 7A and 7B, one of the electrodes allowing a main current to flow through the switching element (for example, a collector electrode of the IGBT element 711 or a drain electrode of the power MOSFET element) is provided on a lower surface, and the electrode on the lower surface is bonded to the conductor pattern of the wiring board 5 by a bonding material such as solder. The other of the electrodes allowing the main current to flow through the switching element (for example, an emitter electrode of the IGBT element 711 or a source electrode of the power MOSFET element) is provided on the upper surface of each of the semiconductor elements 7A and 7B, and is connected to the conductor pattern of the wiring board 5 by a wiring member such as the lead 8. Furthermore, a gate electrode for controlling the operation of the switching element is provided on the upper surface of each of the semiconductor elements 7A and 7B. The gate electrodes of the semiconductor elements 7A and 7B are electrically connected to the control terminals 14A and 14B provided in the case 6, respectively, via wiring members, the conductor patterns of the wiring board 5, and the like.

The semiconductor elements used in the inverter circuit 200 are not limited to those in which a switching element and a diode element are formed, such as the above-described RC-IGBT elements. For example, the inverter circuit 200 may have a configuration in which a semiconductor element having a switching element such as an IGBT element formed therein and a semiconductor element having a diode element used as an FWD formed therein are connected by a wiring member. Between the first main terminal 11 and the third main terminal 13, and between the third main terminal 13 and the second main terminal 12, a plurality of sets of the IGBT element 711 and the diode element 712 formed in separate semiconductor elements may be connected in parallel, respectively. A semiconductor substrate forming the switching element and the diode element in the semiconductor element is not limited to a silicon (Si) substrate, and may be, for example, a wide bandgap semiconductor substrate such as a silicon carbide (SiC) substrate, a gallium nitride (GaN) substrate, or the like.

In the case 6, an insulating resin component 600 having a peripheral wall portion that surrounds the wiring board 5 and the semiconductor elements 7A and 7B in plan view of the upper surface of the heat dissipation plate 4, and a plurality of terminal components (for example, the main terminals 11 to 13, the control terminals 14A and 14B, and the auxiliary control terminals 15A and 15B) are integrally formed by insert molding. As described above, each of the terminal components includes an inner terminal portion extending into the space surrounded by the peripheral wall portion of the insulating resin component 600 and an outer terminal portion exposed along the upper surface of the insulating resin component 600.

In the first main terminal 11, an inner terminal portion 1101 is connected to a collector electrode of the semiconductor element 7A, and an outer terminal portion 1102 is connected to a first external terminal 21 of the capacitor module 3 (refer to FIG. 4). In the second main terminal 12, an inner terminal portion 1201 is connected to an emitter electrode of the semiconductor element 7B, and an outer terminal portion 1202 is connected to a second external terminal 22 of the capacitor module 3. In the third main terminal 13, an inner terminal portion is connected to an emitter electrode of the semiconductor element 7A and a collector electrode of the semiconductor element 7B, and an outer terminal portion is connected to a load. The capacitor module 3 includes a capacitor 23 that is connected in parallel with the inverter circuit 200 illustrated in FIG. 4 and functions as a smoothing capacitor in the power conversion device including the semiconductor device 1. One electrode of the capacitor 23 is connected to the first external terminal 21, and the other electrode thereof is connected to the second external terminal 22. The first external terminal 21 and the second external terminal 22 of the capacitor module 3 in the semiconductor device 1 of the present embodiment each extend in the-Y direction from a side surface 301 facing the semiconductor module 2 in a housing that accommodates the capacitor 23. In the semiconductor device 1 illustrated in FIG. 1, the first external terminal 21 extends from the side surface 301 of the housing as a single terminal shared by the three inverter circuits 200 of the semiconductor module 2, and the second external terminal 22 extends from the side surface 301 of the housing as separate terminals 22U, 22V, and 22W provided for each inverter circuit 200.

In the semiconductor module 2 of the present embodiment, the outer terminal portion 1102 of the first main terminal 11 and the outer terminal portion 1202 of the second main terminal 12 are disposed in the Y direction in a portion of the insulating resin component 600, which is located further toward the positive side in the Y direction than the space in which the semiconductor elements 7A and 7B and the like are disposed. More specifically, in plan view, the outer terminal portion 1202 of the second main terminal 12 is disposed between the outer terminal portion 1102 of the first main terminal 11 and the end side of the insulating resin component 600 on the positive side in the Y direction. As illustrated in FIG. 3, the outer terminal portion 1102 of the first main terminal 11 has a region overlapping a routing portion between the inner terminal portion 1201 and the outer terminal portion 1202 of the second main terminal 12 in plan view, and the overlapping region is insulated from the routing portion of the second main terminal 12 by the insulating resin component 600.

The control terminal 14A and the auxiliary control terminal 15A are connected to the gate electrode and the emitter electrode of the semiconductor element 7A, respectively. The outer terminal portions of the control terminal 14A and the auxiliary control terminal 15A are connected to a gate drive circuit that generates a control signal to be applied to a gate of a switching element (for example, the IGBT element 711) of the semiconductor element 7A. The control terminal 14B and the auxiliary control terminal 15B are connected to the gate electrode and the emitter electrode of the semiconductor element 7B, respectively. The outer terminal portions of the control terminal 14B and the auxiliary control terminal 15B are connected to a gate drive circuit that generates a control signal to be applied to a gate of a switching element (for example, the IGBT element 711) of the semiconductor element 7B. The auxiliary control terminals 15A and 15B may be referred to as auxiliary emitter terminals, emitter sense terminals, or the like in a case in which the switching element is the IGBT element 711, and may be referred to as auxiliary source terminals or the like in a case in which the switching element is a power MOSFET element. The terminal components of the case 6 may include an additional auxiliary control terminal connected to a temperature sensing unit, which may be included in the semiconductor device 1, and to temperature sensing electrodes for measuring the temperatures of the semiconductor elements 7A and 7B.

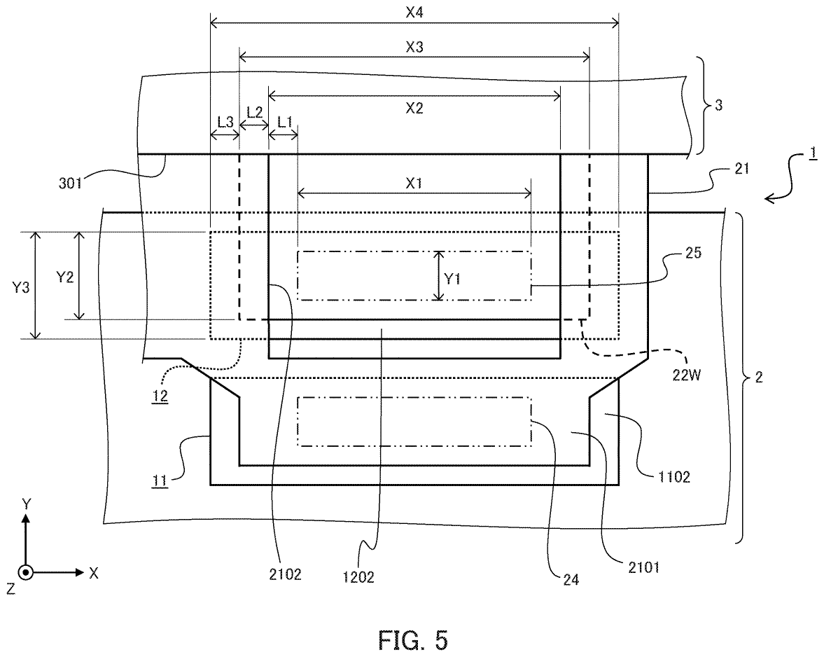

FIG. 5 is a partially enlarged top view illustrating a first example of the shapes of the first main terminal and the second main terminal of the semiconductor module and the first external terminal and the second external terminal of the capacitor module. FIG. 5 illustrates, in an enlarged manner, a connection portion between the first main terminal 11 and the second main terminal 12 of the inverter circuit 200W at the right end of the semiconductor device 1 of FIG. 1, and the first external terminal 21 and the second external terminal 22W of the capacitor module 3. A connection portion between the first main terminal 11 and the second main terminal 12 of the other inverter circuit 200U (or 200V) and the first external terminal 21 and the second external terminal 22U (or 22V) of the capacitor module 3 may have a similar configuration. In the following description, a “plan view” in which a plane is not specified is intended to mean an XY plan view.

The first external terminal 21 of the capacitor module 3 includes a to-be-connected portion 2101 that overlaps the upper surface of the outer terminal portion 1102 of the first main terminal 11 in the inverter circuit 200W in plan view of the upper surface of the semiconductor module 2, and that is connected to the first main terminal 11. In addition, the first external terminal 21 has an opening region 2102 that encloses at least a portion of an overlapping region in which the outer terminal portion 1202 of the second main terminal 12 of the semiconductor module 2 and a to-be-connected portion of the second external terminal 22W of the capacitor module 3 overlap each other in plan view. The opening region 2102 of the first external terminal 21 is located between the to-be-connected portion 2101 and the side surface 301 of the capacitor module 3 in plan view. The opening region 2102 illustrated in FIG. 5 is a rectangle having a side extending in the X direction and a side extending in the Y direction, and an end on the positive side in the Y direction reaches the side surface 301 of the capacitor module 3. In FIG. 5, the second external terminal 22W located on the back side (on the negative side in the Z direction) of the first external terminal 21 has a first region located within the opening region 2102 of the first external terminal 21 in plan view, and regions located on the positive side in the X direction and the negative side in the X direction of the first region and formed to overlap the first external terminal 21. In FIG. 5, among the outlines of the second external terminal 22W, a section that passes through the opening region 2102 of the first external terminal 21 and is visible in plan view is indicated by a solid line, and a section that is not visible due to the first external terminal 21 is indicated by a broken line. In addition, in FIG. 5, among the outlines of the semiconductor module 2, the first main terminal 11, and the second main terminal 12, a section that is visible in plan view is indicated by a solid line, and a section that is not visible because the first external terminal 21 and/or the second external terminal 22W overlap each other is indicated by a dotted line.

As described above, in the first external terminal 21 of the capacitor module 3 according to the present embodiment, between the to-be-connected portion 2101 connected to the outer terminal portion 1102 of the first main terminal 11 of the semiconductor module 2 and the side surface 301 of the housing, there is provided the opening region 2102 that exposes an overlapping region (a connection region) where the second main terminal 12 and the second external terminal 22W located behind the first external terminal 21 (on the negative side in the Z direction) overlap each other in plan view. Therefore, the outer terminal portion 1202 of the second main terminal 12 and the to-be-connected portion of the second external terminal 22W can be bonded to each other by, for example, laser beam welding in which the to-be-connected portion of the second external terminal 22W is irradiated with a laser beam through the opening region 2102 of the first external terminal 21. That is, the outer terminal portion 1202 of the second main terminal 12 and the to-be-connected portion of the second external terminal 22W can be bonded by irradiating the inside of a single bonding region 25 enclosed by the opening region 2102 of the first external terminal 21 with a laser beam in plan view.

When the outer terminal portion 1202 of the second main terminal 12 and the to-be-connected portion of the second external terminal 22W are bonded to each other by laser beam welding, the opening region 2102 of the first external terminal 21 is formed to have a planar dimension such that the bonding region 25 of the second external terminal 22W and a rectangular annular clearance region surrounding the bonding region 25 are enclosed in the opening region 2102 in plan view. The bonding region 25 is intended to mean a rectangular region circumscribing a region to be irradiated with the laser beam, and a dimension X1 in the X direction and a dimension Y1 in the Y direction may be, for example, X1=15 mm and Y1=3 mm, respectively. The clearance region is, for example, a region that is secured so that a part of the laser beam with which the bonding region 25 is irradiated does not hit the first external terminal 21, and a width L1 in the X direction may be, for example, 2 mm. In this case, a dimension X2 (=X1+2×L1) in the X direction of the opening region 2102 illustrated in FIG. 5 may be 19 mm.

In the second external terminal 22W illustrated in FIG. 5, a dimension X3 in the X direction is smaller than a dimension X4 in the X direction of the outer terminal portion 1202 of the second main terminal 12, and is larger than the dimension X2 in the X direction of the opening region 2102 of the first external terminal 21. In this example, a dimension L2 in the X direction of a region overlapping the first external terminal 21 at both ends of the second external terminal 22W in the X direction may be, for example, 2 mm, and a difference (2×L3) between the dimension X3 in the X direction of the second external terminal 22W and the dimension in the X direction of the outer terminal portion 1202 of the second main terminal 12 may be, for example, 4 mm (that is, a dimension L3 can be 2 mm). Therefore, when the dimension X1 in the X direction of the bonding region 25 is 15 mm as described above, the dimension in the X direction X4 of the outer terminal portion 1202 of the second main terminal 12 is about 27 mm.

Further, the position in the Y direction of the end portion on the negative side in the Y direction in the opening region 2102 of the first external terminal 21 (in other words, the end portion located between a bonding region 24 and the bonding region 25) is set such that a distance from the bonding region 24 and a distance from the bonding region 25 satisfy a predetermined clearance. The bonding region 24 is a region to be irradiated with a laser beam in the to-be-connected portion 2101 of the first external terminal 21, where the to-be-connected portion 2101 overlaps the outer terminal portion 1102 of the first main terminal 11 in plan view. The distance from the bonding region 24 may be, for example, a distance secured to prevent a part of the laser beam from passing through the opening region 2102 of the first external terminal 21 and hitting a lower layer member in the step of irradiating the bonding region 24 with the laser beam. The distance from the bonding region 25 may be a distance secured to prevent a part of the laser beam with which the inside of the bonding region 25 is irradiated from hitting the first external terminal 21.

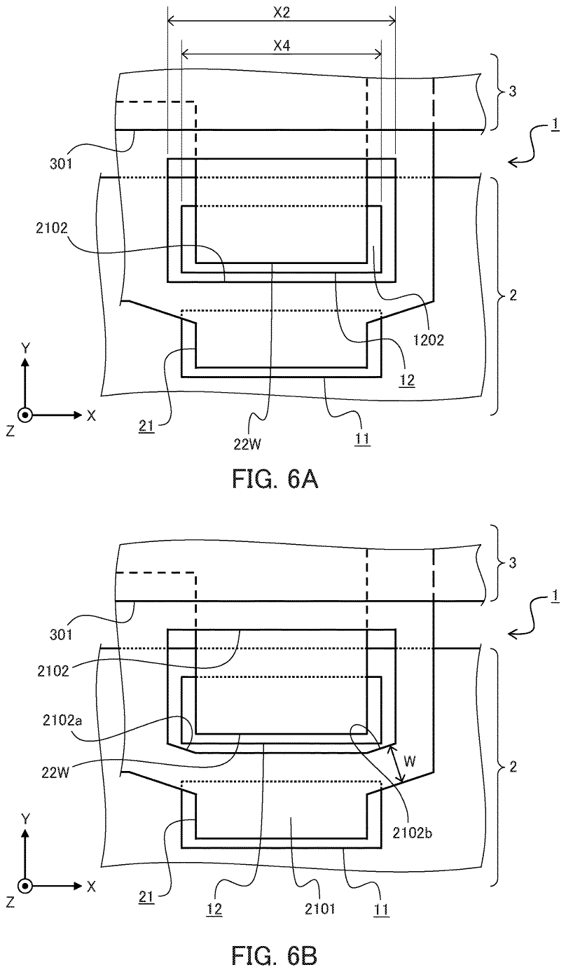

Further, as illustrated in FIG. 5, the position in the Y direction of the end portion on the positive side in the Y direction of the opening region 2102 of the first external terminal 21 (in other words, the end portion located between the bonding region 25 and the side surface 301 of the housing of the capacitor module 3) is preferably the position of the side surface 301 of the housing of the capacitor module 3. That is, by maximizing the dimension in the Y direction of the opening region 2102 (the extending direction of the second external terminal 22W), the effect of preventing heat from being trapped between the first external terminal 21 and the second external terminal 22W, which are arranged in a stacked manner at a predetermined interval, is enhanced. Note that the position of the end portion on the positive side in the Y direction in the opening region 2102 of the first external terminal 21 only needs to be set such that the distance from the bonding region 25 satisfies a predetermined clearance, and does not necessarily reach the side surface 301 of the housing of the capacitor module 3, as will be described later with reference to FIGS. 6A and 6B.

When the dimension Y1 in the Y direction of the bonding region 25 illustrated in FIG. 5 is 3 mm, a dimension Y2 in the Y direction of an overlapping region between the to-be-connected portion of the second external terminal 22W and the outer terminal portion 1202 of the second main terminal 12 may be set to, for example, 9 mm. A dimension Y3 in the Y direction of the outer terminal portion 1202 of the second main terminal 12 may satisfy a size relationship of Y>Y2 with respect to the dimension Y2 in the Y direction of the overlapping region as illustrated in FIG. 5, but the present invention is not limited thereto, and a dimensional difference Y3-Y2 may be 0.

FIGS. 6A and 6B are partially enlarged top views illustrating another example of the shapes of the first main terminal and the second main terminal of the semiconductor module and the first external terminal and the second external terminal of the capacitor module. In addition, in FIGS. 6A and 6B, among the outlines of the semiconductor module 2, the first main terminal 11, and the second main terminal 12, a section that is visible in plan view is indicated by a solid line, and a section that is not visible because the first external terminal 21 or the second external terminal 22W overlaps the front side (the positive side in the Z direction) is indicated by a dotted line. Further, among the outlines of the second external terminal 22W, a section that is visible in plan view is indicated by a solid line, and a section that is not visible because the first external terminal 21 overlaps the front side (the positive side in the Z direction) is indicated by a broken line.

In the first external terminal 21 of the capacitor module 3 illustrated in FIG. 6A, the dimension X2 in the X direction of the opening region 2102 is larger than the dimension X4 in the X direction of the outer terminal portion 1202 of the second main terminal 12 of the semiconductor module 2. In other words, in the semiconductor module 2 illustrated in FIG. 6A, an area of the outer terminal portion 1202 of the second main terminal 12 can be reduced based on the dimension of the single bonding region 25 (refer to FIG. 5). Therefore, for example, as compared with a semiconductor device in which the dimension, the position, and the like of the outer terminal portion 1202 of the second main terminal 12 are set so as to obtain a bonding region that does not overlap the first external terminal having no opening region 2102 in plan view, the amount (volume) of a conductive material used for forming the second main terminal 12 can be reduced, thereby making it possible to lower manufacturing costs of the semiconductor module 2. Further, as illustrated in FIG. 6A, the position of the end portion on the positive side in the Y direction of the opening region 2102 of the first external terminal 21 may be closer to the bonding region side than the side surface 301 of the housing of the capacitor module 3. Since the first external terminal 21 is formed in a single plate shape at the position of the side surface 301 of the housing of the capacitor module 3, the first external terminal 21 is less likely to be deformed at the position of the side surface 301 of the capacitor module 3 as compared with a case in which the first external terminal 21 is divided into a plurality of separate portions by the opening region 2102 at the position of the side surface 301 of the capacitor module 3, as illustrated in FIG. 5. Therefore, it is possible to prevent deterioration in alignment accuracy between the to-be-connected portion of the first external terminal 21 and the outer terminal portion 1102 of the first main terminal 11 due to, for example, the deformation of the first external terminal 21.

In addition, in a case in which the opening region 2102 of the first external terminal 21 has a rectangular shape in plan view, a cross-sectional area of a current path between the to-be-connected portion 2101 of the first external terminal 21 and the capacitor 23 (refer to FIG. 4) may be reduced around the end portion on the negative side in the Y direction (that is, in FIG. 5, the end portion located between the bonding region 24 and the bonding region 25), which may restrict the current flow. Therefore, for example, as illustrated in FIG. 6B, the opening region 2102 of the first external terminal 21 may have a shape in which its end portion on the negative side in the Y direction located between the bonding region 24 and the bonding region 25 suppresses a decrease in the cross-sectional area of the first external terminal 21. The opening region 2102 illustrated in FIG. 6B suppresses a decrease in the cross-sectional area of the first external terminal 21 by providing sections 2102a and 2102b, which are inclined with respect to the X direction and the Y direction, at both ends in the X direction at the end portion on the negative side in the Y direction (lower-left and lower-right corner portions in the drawing) to widen the width W in plan view. Note that the shape of the opening region 2102 for suppressing the decrease in the cross-sectional area of the first external terminal 21 can be modified within a range that allows the outer terminal portion 1202 of the second main terminal 12 and the second external terminal 22W to be connected within the opening region 2102, and is not limited to a specific shape.

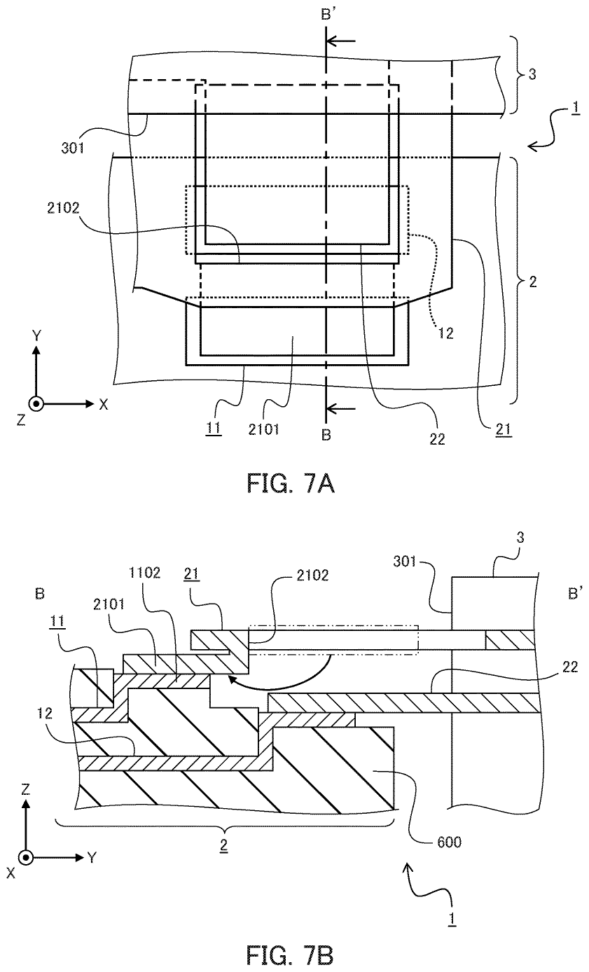

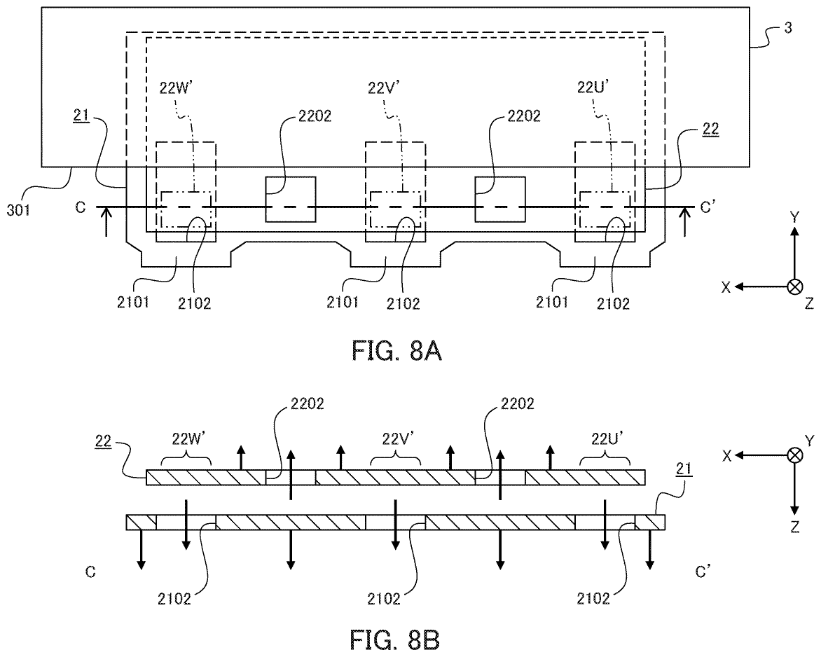

FIG. 7A is a partially enlarged top view illustrating a modification of the first external terminal of the capacitor module, and FIG. 7B is a cross-sectional view at a position of an alternate long and short dash line B-B′ in FIG. 7A. FIG. 8A is a bottom view illustrating a modification of the second external terminal of the capacitor module, and FIG. 8B is a cross-sectional view at a position of an alternate long and short dash line C-C′ in FIG. 8A. In addition, in FIG. 7A, among the outlines of the semiconductor module 2, the first main terminal 11, and the second main terminal 12, a section that is visible in plan view is indicated by a solid line, and a section that is not visible because the first external terminal 21 or the second external terminal 22W overlaps the front side (the positive side in the Z direction) is indicated by a dotted line. In addition, among the outlines of the second external terminal 22W, a section that is visible in plan view is indicated by a solid line. Further, among the outlines of the first external terminal 21 and the second external terminal 22W, a section that is not visible because the section is located inside the housing of the capacitor module 3 is indicated by a broken line.

The first external terminal 21 in the capacitor module 3 according to the present embodiment is not limited to one manufactured by a specific manufacturing method. The first external terminal 21 illustrated in FIG. 5 and the like may be, for example, one in which the opening region 2102 is formed by punching using a mold (punch). However, the first external terminal 21 is not limited to such a configuration, and as illustrated in FIGS. 7A and 7B, a part or all of the portion that becomes unnecessary by forming the opening region 2102 may be bent to serve as the to-be-connected portion 2101 to be bonded to the outer terminal portion 1102 of the first main terminal 11. In the example of FIGS. 7A and 7B, when the opening region 2102 is formed in the first external terminal 21, sides at both ends in the X direction and a side on the positive side in the Y direction in the outline of a region to become the opening region 2102 are cut. Thereafter, a portion remaining in the region to become the opening region 2102 (for example, a portion in the rectangular region indicated by a two-dot chain line in FIG. 7B) is bent at the side on the negative side in the Y direction in the contour of the region to become the opening region 2102, thereby providing the to-be-connected portion 2101 of the first external terminal 21. At this time, the portion to be bent to form the opening region 2102 may be bent upward instead of being bent downward, as illustrated in FIGS. 7A and 7B. In the first external terminal 21 illustrated in FIGS. 7A and 7B, the to-be-connected portion 2101 protruding toward the negative side in the Y direction from an annular region surrounding the opening region 2102 as described with reference to FIG. 5 and the like is formed by a portion that becomes unnecessary by forming the opening region 2102. Therefore, the planar dimension of the conductive material necessary for forming the first external terminal 21 can be reduced, and thus an increase in manufacturing costs of the capacitor module 3 (the semiconductor device 1) can be suppressed.

In addition, in the semiconductor device 1 of the present embodiment, the shape of the second external terminal 22 of the capacitor module 3 is not limited to a shape extending from the side surface of the housing as the separate external terminals 22U, 22V, and 22W provided for each of the above-described inverter circuits 200. As illustrated in FIGS. 8A and 8B, the second external terminal 22 of the capacitor module 3 may extend from the side surface 301 of the housing of the capacitor module 3 as a single (one-piece) plate-like member shared by the three inverter circuits 200. Regions denoted by reference numerals 22U′, 22V′, and 22W′ in the second external terminal 22 in FIGS. 8A and 8B may be regions that respectively include the bonding regions with the second main terminals 12 of the semiconductor module 2 and the clearance regions around the bonding regions in the external terminals 22U, 22V, and 22W illustrated in FIG. 1. In this way, the surface area of the second external terminal 22 can be increased, and the efficiency of heat dissipation from the second external terminal 22 is improved. Furthermore, in a case in which the second external terminal 22 is a single (one-piece) plate-like member shared by the three inverter circuits 200, as illustrated in FIGS. 8A and 8B, an opening region 2202 may be formed in a region of the second external terminal 22 that does not overlap the opening region 2102 of the first external terminal 21. By forming the opening region 2202 in the second external terminal 22, heat can be prevented from being trapped between the first external terminal 21 and the second external terminal 22 arranged in a stacked manner.

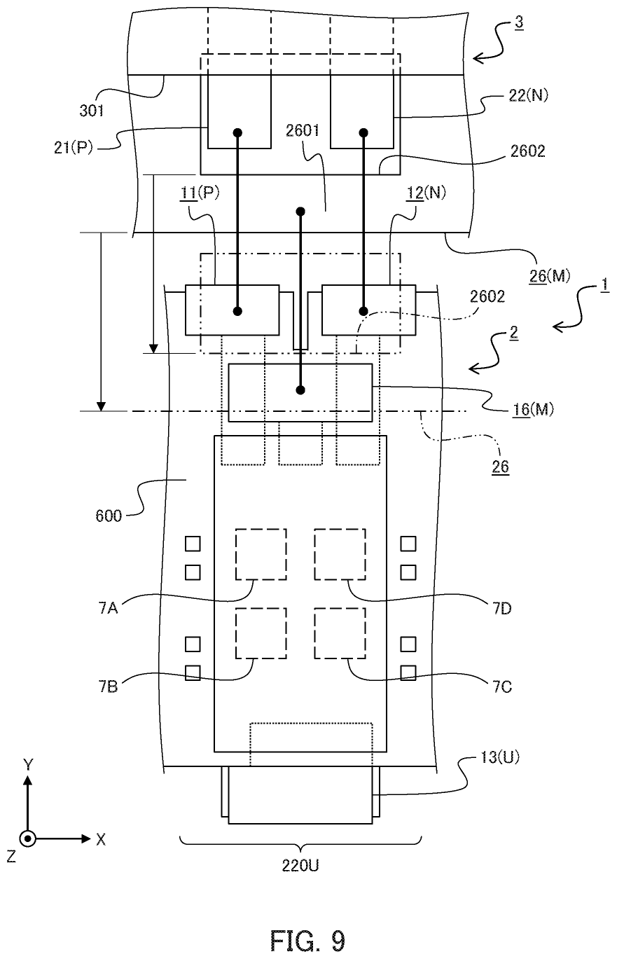

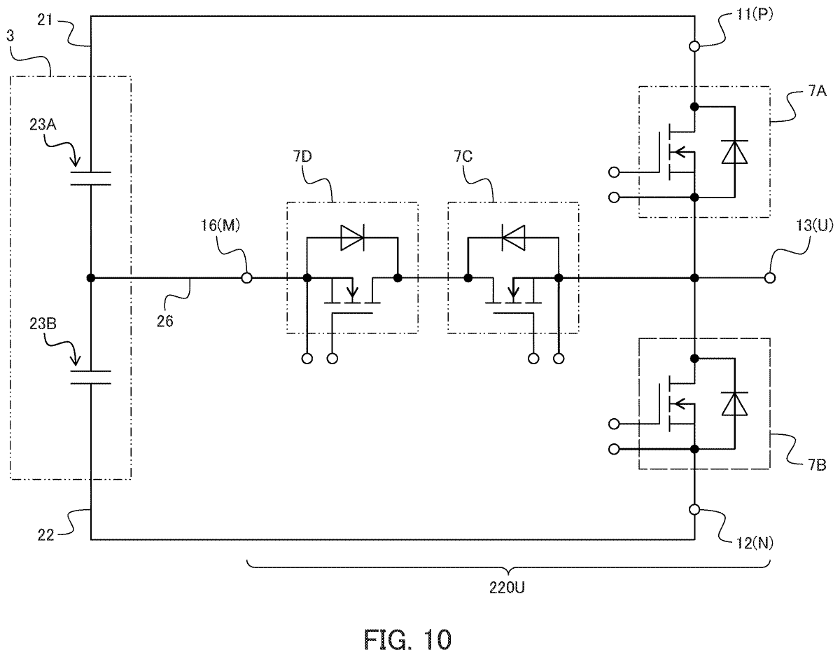

FIG. 9 is a top view illustrating another configuration example of the semiconductor device. FIG. 10 is a circuit diagram illustrating a circuit configuration example of the semiconductor device in FIG. 9. FIG. 9 illustrates only a configuration example of a portion of the semiconductor device 1 where one 3-level inverter circuit 220U is formed. A configuration similar to the portion illustrated in FIG. 9 may be repeated in a portion (not illustrated) extending in the X direction from the portion illustrated in FIG. 9.

The semiconductor module 2 of the semiconductor device 1 of the present embodiment is not limited to one having three main terminals illustrated in FIG. 1, and may have four main terminals as illustrated in FIG. 9. In the semiconductor module 2 illustrated in FIG. 9, the first main terminal 11, the second main terminal 12, and an intermediate terminal 16 are disposed in a portion of the insulating resin component 600 of the case 6, which is located on the positive side in the Y direction relative to a space in which the semiconductor elements 7A to 7D are disposed. Specifically, in plan view, the outer terminal portion 1102 of the first main terminal 11 and the outer terminal portion 1202 of the second main terminal 12 are disposed between an outer terminal portion 1602 of the intermediate terminal 16 and the end side of the insulating resin component 600 on the positive side in the Y direction. The outer terminal portion 1102 of the first main terminal 11 and the outer terminal portion 1202 of the second main terminal 12 are disposed in a direction (X direction) along the end side on the positive side in the Y direction of the insulating resin component 600. In the semiconductor module 2 illustrated in FIG. 9, for example, a 3-level inverter circuit 220U such as that illustrated in FIG. 10 is formed. Although FIG. 10 illustrates a power MOSFET element as an example of the switching element formed in each of the semiconductor elements 7A to 7D, the switching element may be an IGBT element or the like. In addition, the semiconductor element (for example, the semiconductor element 7A) illustrated as one semiconductor element may be a combination of a semiconductor element in which a switching element is formed and a semiconductor element in which a diode element is formed.

The capacitor module 3 connected to the semiconductor module 2 illustrated in FIG. 9 includes the first external terminal 21 connected to the first main terminal 11, the second external terminal 22 connected to the second main terminal 12, and a third external terminal 26 connected to the intermediate terminal 16. A first capacitor 23A and a second capacitor 23B are disposed in the housing of the capacitor module 3. One electrode of the first capacitor 23A is connected to the first external terminal 21, and the other electrode thereof is connected to the third external terminal 26. One electrode of the second capacitor 23B is connected to the third external terminal 26, and the other electrode thereof is connected to the second external terminal 22.

In the capacitor module 3 connected to the semiconductor module 2 illustrated in FIG. 9, for example, an opening region 2602 is formed in the third external terminal 26 connected to the outer terminal portion of the intermediate terminal 16 farthest from the side surface 301 of the housing of the capacitor module 3 in the semiconductor module 2. The opening region 2602 of the third external terminal 26 is formed to have dimensions such that, when a to-be-connected portion 2601 located on the negative side in the Y direction relative to the opening region 2602 is connected to the intermediate terminal 16, the opening region 2602 encloses at least a portion of an overlapping region between the first main terminal 11 and the first external terminal 21 and at least a portion of an overlapping region between the second main terminal 12 and the second external terminal 22 in plan view. Note that the opening region 2602 of the third external terminal 26, the first external terminal 21, and the second external terminal 22 may be formed to have dimensions such that the end portion of the first external terminal 21 on the negative side in the X direction and the end portion of the second external terminal 22 on the positive side in the X direction overlap the third external terminal 26.

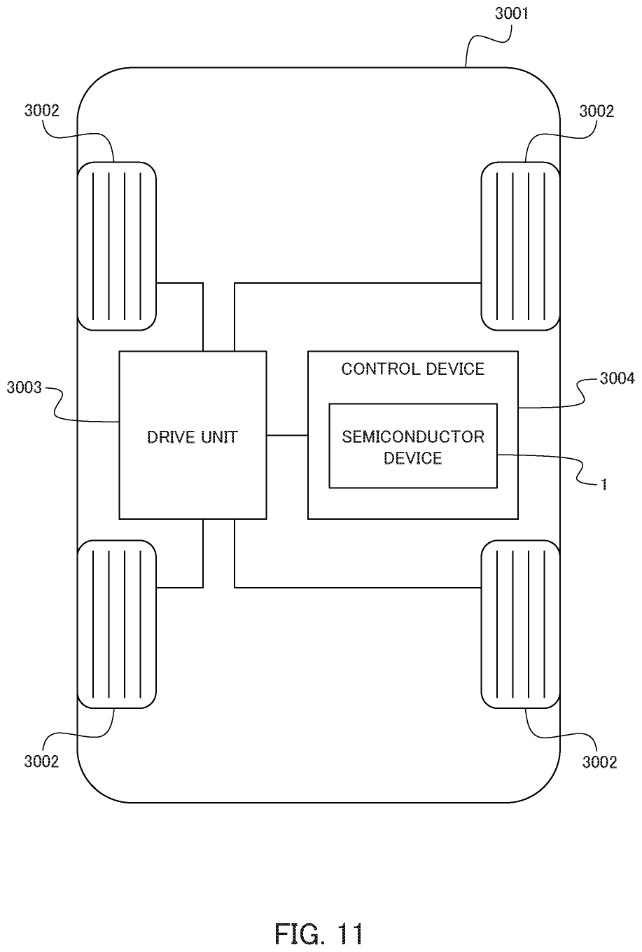

Although the semiconductor device 1 according to the above-described embodiment is not limited to those for specific applications, the semiconductor device 1 including the cooler 9 is particularly suitable for those in which the amount of heat generated by the semiconductor elements during operation is large (those operating at high temperatures). For example, the semiconductor device 1 of the above-described embodiment can be applied to a power conversion device such as an inverter device of an in-vehicle motor. A vehicle to which the semiconductor device 1 according to the present invention is applied will be described with reference to FIG. 11.

FIG. 11 is a schematic plan view illustrating an example of a vehicle to which the semiconductor device according to the embodiment is applied. A vehicle 3001 illustrated in FIG. 11 is, for example, a four-wheeled vehicle including four wheels 3002. The vehicle 3001 may be, for example, an electric vehicle that drives the wheels by a motor or the like, or a hybrid vehicle using the power of an internal combustion engine in addition to the motor. In addition, the vehicle to which the semiconductor device 1 is applied is not limited to a four-wheeled vehicle, and may be, for example, a two-wheeled vehicle or a railway vehicle.

The vehicle 3001 includes a drive unit 3003 that applies power to the wheels 3002, and a control device 3004 that controls the drive unit 3003. The drive unit 3003 may include, for example, at least one of a motor and a hybrid of an engine and a motor.

The control device 3004 performs control (for example, power control) of the drive unit 3003. The control device 3004 includes the semiconductor device 1 including the cooler 9 of the above-described embodiment. The semiconductor device 1 may be configured to perform power control on the drive unit 3003.

The semiconductor device 1 of the above-described embodiment can be applied to, for example, an industrial power conversion device such as an inverter device that drives a motor of an elevator, an escalator, an air-conditioning system of a building, or the like. Further, the circuit formed in the semiconductor module 2 is not limited to the half-bridge inverter circuit illustrated in FIG. 4 or the 3-level inverter circuit illustrated in FIG. 10. The circuit formed in the semiconductor module 2 may be, for example, one having only one half-bridge inverter circuit among the three half-bridge inverter circuits illustrated in FIG. 4. The circuit formed in the semiconductor module 2 may be a full-bridge inverter circuit. Furthermore, the circuit formed in the semiconductor module 2 is not limited to a power conversion circuit that converts direct current into alternating current, and may be another circuit, or may include a power conversion circuit and another circuit.

Furthermore, in the semiconductor device 1 according to the present embodiment, the connection between the first main terminal 11 and the second main terminal 12 of the semiconductor module 2 and the first external terminal 21 and the second external terminal 22 of the capacitor module 3 is not limited to the above-described laser beam welding. For example, another connection method such as ultrasonic bonding may be used, in which energy is directly applied to each of the to-be-connected portion 2101 of the first external terminal 21 and the to-be-connected portion of the second external terminal 22 to perform connection. In addition, for example, in a connection method in which a bonding material such as solder is melted to perform bonding, it is also possible to press the to-be-connected portion 2101 of the first external terminal 21 and the to-be-connected portion of the second external terminal 22 with a jig to prevent positional displacement of the to-be-connected portions.

Hereinafter, feature points in the above-described embodiments will be summarized.

A semiconductor device according to the above-described embodiment includes a semiconductor module in which an outer terminal portion exposed to the outside of a first main terminal and an outer terminal portion exposed to the outside of a second main terminal are disposed adjacent to each other on a first surface of an insulating member, and a capacitor module including a first external terminal and a second external terminal, the first external terminal being connected to the outer terminal portion of the first main terminal, the second external terminal being located between the first external terminal and the second main terminal and being connected to the outer terminal portion of the second main terminal, in which the first external terminal of the capacitor module has a shape having an opening region overlapping the outer terminal portion of the second main terminal in plan view of a connection surface with the outer terminal portion of the first main terminal, and the second external terminal of the capacitor module is connected to a region of the outer terminal portion of the second main terminal, the region being located within the opening region of the first external terminal in the plan view.

In the semiconductor device according to the embodiment, a plurality of sets of the first main terminal and the second main terminal are arranged on the first surface of the insulating member in the semiconductor module, and the first external terminal of the capacitor module is a single terminal in which a portion extending from a housing is connected to the plurality of first main terminals.

In the semiconductor device according to the embodiment, the semiconductor module includes semiconductor elements connected in series between the first main terminal and the second main terminal, and a third main terminal connected between the semiconductor elements connected in series, and the third main terminal is disposed on a side opposite to the first main terminal and the second main terminal across a region in which the semiconductor elements are disposed in the plan view.

In the semiconductor device according to the embodiment, the semiconductor module further includes a third main terminal, the capacitor module further includes a third external terminal located between the first external terminal and the third main terminal and connected to an outer terminal portion of the third main terminal of the semiconductor module, and the third external terminal of the capacitor module is connected to a region of the outer terminal portion of the third main terminal, the region being located within the opening region of the first external terminal in the plan view.

In the semiconductor device according to the embodiment, the semiconductor module further includes semiconductor elements connected in series between the second main terminal and the third main terminal, and the first main terminal is connected between the semiconductor elements connected in series.

In the semiconductor device according to the embodiment, the second external terminal of the capacitor module is a single terminal in which a portion extending from the housing is connected to the plurality of second main terminals.

The vehicle according to the above-described embodiment includes the semiconductor device according to the embodiment.

### INDUSTRIAL APPLICABILITY

As described above, the present invention can facilitate the connection work between the main terminals of the semiconductor module and the external terminals of the capacitor module, and particularly, by applying the present invention to a semiconductor device in which the main terminal of the semiconductor module is disposed along an extending direction of the external terminal from the housing side surface facing the semiconductor module in the capacitor module, the cost of the connection work can be reduced.

The present application is based on Japanese Patent Application No. 2024-112491 filed on Jul. 12, 2024. The entire contents of this application are incorporated herein by reference.

1. A semiconductor device comprising:
a semiconductor module, including
an insulating member having a first surface, and
a first main terminal and a second main terminal each having an outer terminal portion exposed to an outside of the semiconductor module, the outer terminal portion of the first main terminal and the outer terminal portion of the second main terminal being disposed adjacent to each other on the first surface of the insulating member; and
a capacitor module, including
a first external terminal that is connected to the outer terminal portion of the first main terminal with a first connection surface therebetween, and
a second external terminal that is located between the first external terminal and the second main terminal of the semiconductor module, and is connected to a region of the outer terminal portion of the second main terminal, wherein
the first external terminal of the capacitor module has an opening region directly above said region of the outer terminal portion of the second main terminal with respect to a direction perpendicular to the first connection surface.

2. The semiconductor device according to claim 1, wherein
the first main terminal and the second main terminal are both provided in a plurality, and the plurality of first main terminals and the plurality of second main terminals are arranged on the insulating member in the semiconductor module, and
the first external terminal of the capacitor module is a single terminal connected to the plurality of first main terminals.

3. The semiconductor device according to claim 1, wherein
the semiconductor module further includes
a plurality of semiconductor elements connected in series between the first main terminal and the second main terminal, and
a third main terminal connected to a connection node between two adjacent semiconductor elements among the plurality of semiconductor elements connected in series, and
the third main terminal is disposed on a first side of the semiconductor module opposite to a second side of the semiconductor module, the first main terminal and the second main terminal being disposed on the second side, across a region in which the semiconductor elements are disposed in a plan view of the semiconductor device.

4. The semiconductor device according to claim 1, wherein
the semiconductor module further includes a third main terminal having an outer terminal portion,
the capacitor module further includes a third external terminal that is located between the first external terminal and the third main terminal of the semiconductor module, and is connected to a region of the outer terminal portion of the third main terminal, and
said region of the outer terminal portion of the third main terminal is directly below the opening region of the first external terminal with respect to said direction.

5. The semiconductor device according to claim 4, wherein the semiconductor module further includes a plurality of semiconductor elements connected in series between the second main terminal and the third main terminal, and the first main terminal is connected to a connection node between two adjacent semiconductor elements among the plurality of semiconductor elements connected in series.

6. The semiconductor device according to claim 2, wherein the second external terminal of the capacitor module is a single terminal connected to the plurality of second main terminals.

7. A vehicle comprising the semiconductor device according to claim 1.
